(19) United States
(12) Patent Application Publication
(10) Pub. No.: US 2014/0111300 A1
(43) Pub. Date: Apr. 24, 2014

(54) MULTILAYER CERAMIC ELECTRONIC COMPONENT AND METHOD OF MANUFACTURING THE SAME

(71) Applicant: SAMSUNG ELECTRO-MECHANICS CO., LTD., Suwon (KR)

(72) Inventors: Myung Jun Park, Suwon (KR); Kyu Sik Park, Suwon (KR); Young Sook Lee, Suwon (KR); Jae Yeol Choi, Gyunggi-Do (KR); Doo Young Kim, Suwon (KR)

(73) Assignee: SAMSUNG ELECTRO-MECHANICS CO., LTD., Suwon (KR)

(21) Appl. No.: 13/732,074

(22) Filed: Dec. 31, 2012

(30) Foreign Application Priority Data
Oct. 18, 2012 (KR) 10-2012-0115923

(51) Int. Cl. B05D 5/12; H01F 5/00; H01G 4/008; H01C 7/10; H01C 7/00; H01G 4/12; H01L 41/083

(52) U.S. Cl. CPC B05D 5/12; H01G 4/12; H01F 5/00; H01L 41/083; H01C 7/10; H01C 7/00; H01C 7/008; H01G 4/008
USPC 338/22 R; 361/321.2; 336/200; 310/311; 338/21; 338/20; 427/123; 427/125

(57) ABSTRACT

There is provided a method of manufacturing a multilayer ceramic electronic component including: preparing a ceramic body including internal electrodes; forming electrode layers including at least one conductive metal selected from a group consisting of copper (Cu), silver (Ag), palladium (Pd), and platinum (Pt), an alloy thereof, or a coating material and electrically connected to the internal electrodes on external surfaces of the ceramic body; forming nickel (Ni) layers on external surfaces of the electrode layers by a firing method; and forming tin (Sn) layers on external surfaces of the nickel (Ni) layers by a firing method.

### CROSS-REFERENCE TO RELATED APPLICATIONS

This application claims the priority of Korean Patent Application No. 10-2012-0115923 filed on Oct. 18, 2012, in the Korean Intellectual Property Office, the disclosure of which is incorporated herein by reference.

### BACKGROUND OF THE INVENTION

1. Field of the Invention

The present invention relates to a multilayer ceramic electronic component including nickel (Ni) layers and tin (Sn) layers in external electrodes, and a method of manufacturing the same.

2. Description of the Related Art

In general, a capacitor, an inductor, a piezoelectric element, a varistor, a thermistor, and the like are representative electronic components using a ceramic material.

Among these ceramic electronic components, multilayer ceramic capacitors (MLCCs) are electronic components having advantages such as miniaturizability, high capacitance, and ease of mounting.

Multilayer ceramic capacitors are mounted on circuit boards of various electronic products such as display devices, for example, liquid crystal displays (LCDs), plasma display panels (PDPs), or the like, computers, personal digital assistants (PDAs), mobile phones, and the like, to serve to charge or discharge electricity.

Recently, due to the enlargement of a size of the display device, an increase in central processing unit (CPU) speeds, or the like, the generation of heat in electronic devices has significantly increased.

Therefore, stable capacitance and reliability should be secured in multilayer ceramic capacitors, even when operated at high temperatures, for the stable operation of integrated circuits (ICs) installed in electronic devices.

In addition, recently, as electronic products have gradually been miniaturized, microminiaturization and super high capacitance of the multilayer ceramic capacitor used in the electronic products have been required.

Therefore, as external electrodes have been gradually thinned for microminiaturization and high multilayering of products, a thickness of the external electrode formed by a plating method has been gradually reduced. Accordingly, since external electrode compactness may not be secured with reduced thicknesses thereof, an electrolyte material may infiltrate into a ceramic body during plating processes of forming a nickel (Ni) layer and a tin (Sn) layer, such that product reliability may be deteriorated.

Therefore, in order to prevent reductions in the compactness of the external electrode due to reductions in the thickness thereof and infiltration of the electrolyte material into the ceramic body due thereto, in the present invention, a nickel (Ni) layer and a tin (Sn) layer are formed with a firing method rather than a plating method.

### RELATED ART DOCUMENT

(Patent Document 1) Korean Patent Laid-Open Publication No. 2012-0016005
(Patent Document 2) Korean Patent Laid-Open Publication No. 2012-0073636

### SUMMARY OF THE INVENTION

An aspect of the present invention provides a multilayer ceramic electronic component having improved reliability by including nickel (Ni) layers and tin (Sn) layers in external electrodes, and a method of manufacturing the same.

According to an aspect of the present invention, there is provided a method of manufacturing a multilayer ceramic electronic component including: preparing a ceramic body including internal electrodes; forming electrode layers including at least one conductive metal selected from a group consisting of copper (Cu), silver (Ag), palladium (Pd), and platinum (Pt), an alloy thereof, or a coating material and electrically connected to the internal electrodes on external surfaces of the ceramic body; forming nickel (Ni) layers on external surfaces of the electrode layers by a firing method; and forming tin (Sn) layers on external surfaces of the nickel (Ni) layers by a firing method.

The nickel (Ni) layers and the tin (Sn) layers have a thickness of 1 to 10 μm

The nickel (Ni) layers may have a thickness of 0.1 to 10 μm.

The tin (Sn) layers may have a thickness of 0.1 to 10 μm.

The nickel (Ni) layers may be fired at a temperature of 600 to 900° C.

The tin (Sn) layers may be fired at a temperature of 200 to 400° C.

According to another aspect of the present invention, there is provided a multilayer ceramic electronic component including: a ceramic body including dielectric layers; internal electrodes disposed to face each other and having the dielectric layers interposed therebetween; and external electrodes electrically connected to the internal electrodes, wherein the external electrodes include: electrodes layers formed of at least one conductive metal selected from a group consisting of copper (Cu), silver (Ag), palladium (Pd), and platinum (Pt), an alloy thereof, or a coating material and electrically connected to the internal electrodes; nickel (Ni) layers formed on external surfaces of the electrode layers; and tin (Sn) layers formed on external surfaces of the nickel (Ni) layers, wherein the nickel (Ni) layers and the tin (Sn) layers have a thickness of 1 to 10 μm.

The nickel (Ni) layers may have a thickness of 0.1 to 10 μm.

The tin (Sn) layers may have a thickness of 0.1 to 10 μm.

The nickel (Ni) layers may be fired at a temperature of 600 to 900° C.

The tin (Sn) layers may be fired at a temperature of 200 to 400° C.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a multilayer ceramic electronic component according to an embodiment of the present invention;

FIG. 2 is a cross-sectional view taken along line A-A′ of FIG. 1;

FIG. 3 is a flow chart schematically showing a method of manufacturing an electronic component according to the embodiment of the present invention;

FIGS. 4A through 4D are cross-sectional views describing the method of manufacturing an electronic component of FIG. 3; and

FIG. 5 is a photograph showing a nickel (Ni) layer according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

The present invention relates to a multilayer ceramic electronic component. An example of the multilayer ceramic electronic components according to the embodiment of the present invention may include a multilayer ceramic capacitor, an inductor, a piezoelectric element, a varistor, a chip resistor, a thermistor, and the like. Hereinafter, a multilayer ceramic capacitor will be described as an example of the multilayer ceramic electronic component.

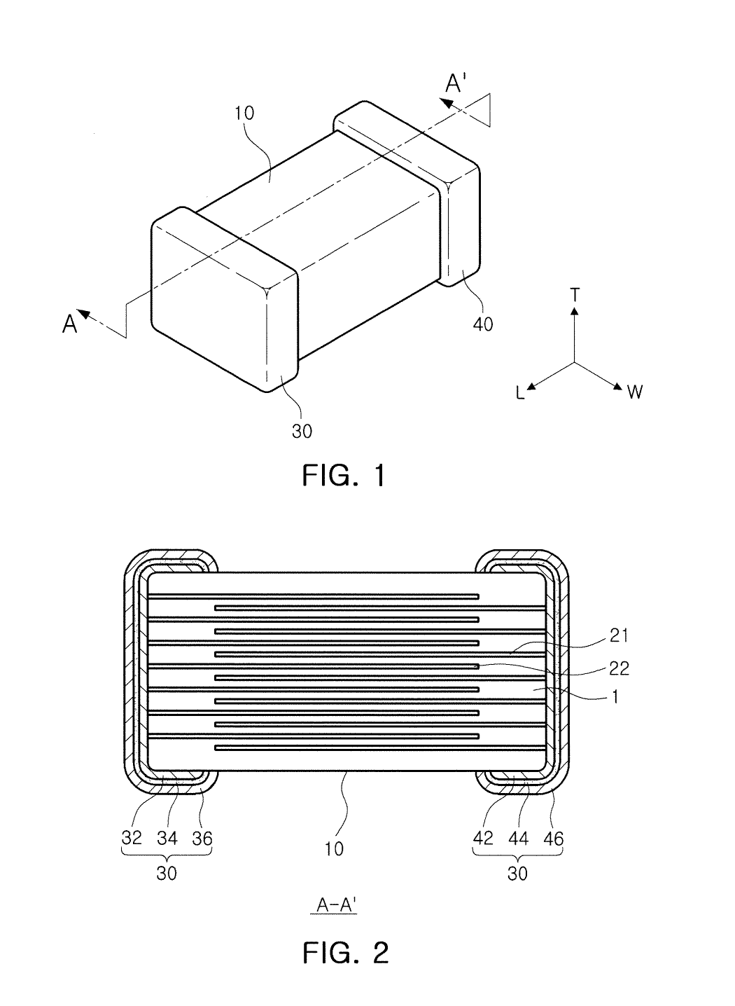

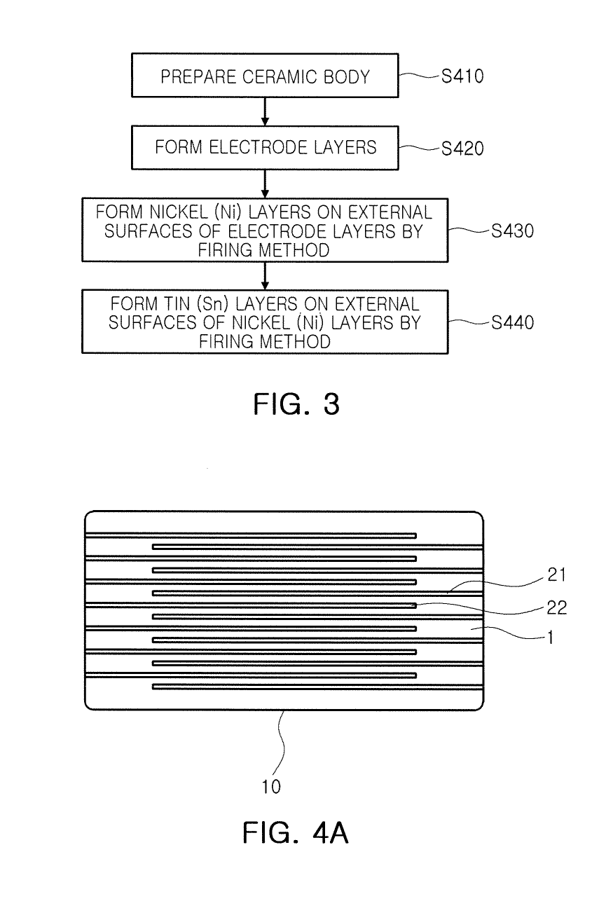

FIG. 1 is a perspective view schematically showing a multilayer ceramic electronic component according to an embodiment of the present invention, and FIG. 2 is a cross-sectional view taken along line A-A′ of FIG. 1.

Referring to FIGS. 1 and 2, an electronic component according to the embodiment of the present invention, a multilayer ceramic capacitor, may include a ceramic body 10, internal electrodes 21 and 22, and external electrodes 30 and 40.

The ceramic body 10 may be formed by stacking and then sintering a plurality of dielectric layers 1, wherein adjacent dielectric layers 1 may be integrated such that a boundary therebetween may not be readily apparent. The dielectric layers 1 may be formed of a ceramic material having a high degree of permittivity, but is not limited thereto. That is, the dielectric layers 1 may be formed of a barium titanate (BaTiO3)-based material, a lead complex perovskite-based material, a strontium titanate (SrTiO3)-based material, or the like.

The ceramic body 10 may be have the internal electrodes 21 and 22 formed therein, and outer surfaces thereof may be provided with the external electrodes 30 and 40.

The internal electrodes 21 and 22 may be disposed such that they are interposed between the dielectric layers 1 in a process of stacking the plurality of dielectric layers 1.

The internal electrodes 21 and 22, pairs of electrodes having different polarities, may be alternately disposed to face each other in a direction in which the dielectric layers 1 are stacked and are electrically insulated from each other by the dielectric layers 1.

One ends of the internal electrodes 21 and 22 as described above may be alternately exposed to end surfaces of the ceramic body 10. In this case, respective one ends of the internal electrodes 21 and 22 exposed to the end surfaces of the ceramic body 10 may be electrically connected to the respective external electrodes 30 and 40.

The internal electrodes 21 and 22 may be formed of a conductive metal. Here, the conductive metal is not particularly limited. For example, silver (Ag), lead (Pb), platinum (Pt), nickel (Ni), copper (Cu), or the like, may be used alone, or a mixture of at least two thereof may be used as the conductive metal.

The external electrodes 30 and 40 may be formed to be electrically connected to one ends of the internal electrodes 21 and 22 exposed to the end surfaces of the ceramic body 10. Therefore, the external electrodes 30 and 40 may be formed on both ends of the ceramic body 10, respectively.

As shown in FIG. 2, the external electrodes 30 and 40 according to the embodiment of the present invention may include electrode layers 32 and 42, nickel (Ni) layers 34 and 44, and tin (Sn) layers 36 and 46.

The electrode layers 32 and 42 may be formed of copper (Cu), silver (Ag), palladium (Pd), or platinum (Pt). Therefore, the electrode layers 32 and 42 according to the embodiment of the present invention may be formed by applying a conductive paste containing a copper (Cu) powder, a silver (Ag) powder, a palladium (Pd) powder, or a platinum (Pt) powder to external surfaces of the ceramic body 10 and firing the applied conductive paste. Here, a method of applying the conductive paste is not particularly limited. For example, various methods such as a dipping method, a painting method, a printing method, or the like, may be used.

The nickel (Ni) layers 34 and 44 may be formed on outer surfaces of the electrode layers 32 and 42. The nickel (Ni) layers 34 and 44 according to the embodiment of the present invention may be formed by applying a conductive paste containing a nickel powder to external surfaces of the electrode layers 32 and 42 and firing the applied conductive paste, similarly to the electrode layers 32 and 42. Here, a method of applying the conductive paste is not particularly limited. For example, various methods such as a dipping method, a painting method, a printing method, or the like, may be used.

The tin (Sn) layers 36 and 46 may be formed on external surfaces of the nickel (Ni) layers 34 and 44. The tin (Sn) layers 36 and 46 according to the embodiment of the present invention may be formed by applying a conductive paste containing a tin powder to the external surfaces of the nickel (Ni) layers 34 and 44 and firing the applied conductive paste, similarly to the nickel (Ni) layers 34 and 44. Here, a method of applying the conductive paste is not particularly limited. For example, various methods such as a dipping method, a painting method, a printing method, or the like, may be used.

In addition, a firing temperature of the nickel (Ni) layers 34 and 44 may be 600 to 900° C., and a firing temperature of the tin (Sn) layers 36 and 46 may be 200 to 400° C. In the case in which the nickel (Ni) layers 34 and 44 and the tin (Sn) layers 36 and 46 are formed by a firing method, although the electrode layers 32 and 42 have gaps present therein and are not compact, since there is no risk that reliability will be deteriorated by a plating solution, the electrode layers 32 and 42 formed of the copper (Cu), silver (Ag), palladium (Pd), or platinum (Pt) only need to maintain electrical contact and coupling force between the internal electrodes 21 and 22 and the external electrodes 30 and 40.

Therefore, in order to secure design capacity of the ceramic body 10 in a maximal level, the nickel (Ni) layers 34 and 44 and the tin (Sn) layers 36 and 46 need to have a thickness of 1 to 10 μm. However, since the nickel (Ni) layers 34 and 44 and the tin (Sn) layers 36 and 46 are formed by a dipping method or a painting method, the thickness thereof may be increased. Therefore, the maximal thickness of the nickel (Ni) layers 34 and 44 and the tin (Sn) layers 36 and 46 need to be 10 μm or less. In addition, the nickel (Ni) layers 34 and 44 may have a thickness of 0.1 to 10 μm, and the tin (Sn) layers 36 and 46 may have a thickness of 0.1 to 10 μm.

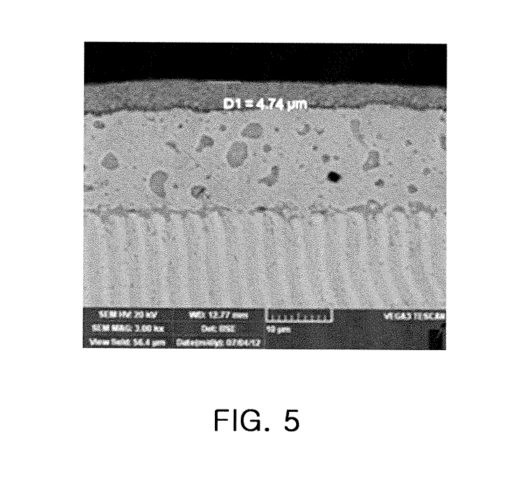

FIG. 5 is a photograph showing that nickel (Ni) layers 34 and 44 formed through a firing method after preparing a conductive paste containing a nickel powder according to the embodiment of the present invention by a dipping method have a thickness of 4.74 μm.

In the nickel (Ni) layers 34 and 44 and the tin (Sn) layers 36 and 46 formed by the firing method, in the case in which the external electrodes 30 and 40 formed by an existing electro-deposition method are not compact, a plating solution may infiltrate into the ceramic body 10, such that plating cracks may be easily generated. However, according to the present invention, in order to block a contact with the plating solution, after the conductive paste containing the nickel powder and the conductive paste containing the tin powder are formed, the external electrodes 30 and 40 are formed by the firing method instead of the existing electro-deposition method, such that compactness and reliability of the external electrodes 30 and 40 may be simultaneously improved.

Hereinafter, a method of manufacturing a multilayer ceramic electronic component according to the embodiment of the present invention will be described below. Although the case in which a method of manufacturing a multilayer ceramic capacitor as the multilayer ceramic electronic component is described by way of example in the embodiment of the present invention, the present invention is not limited thereto.

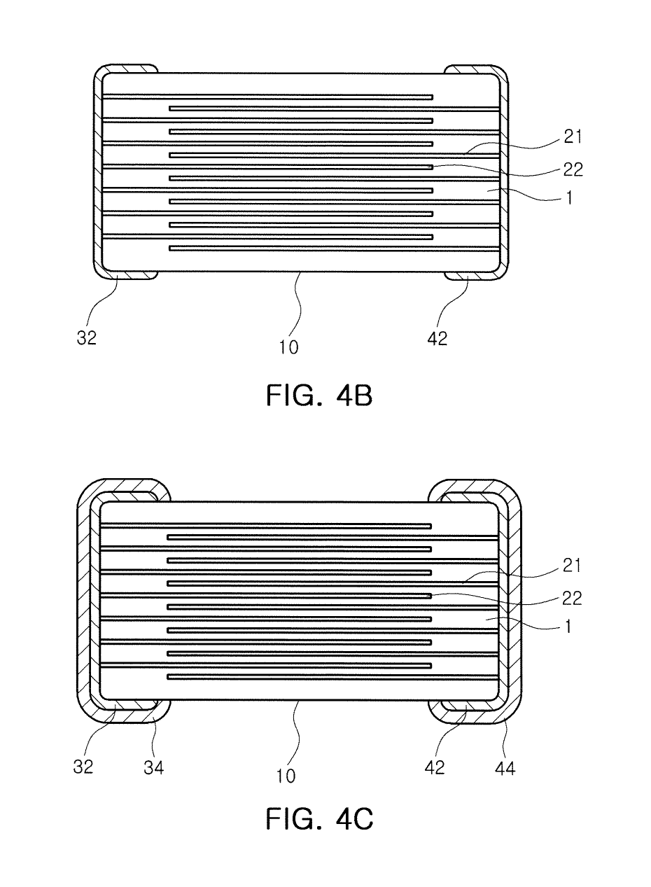

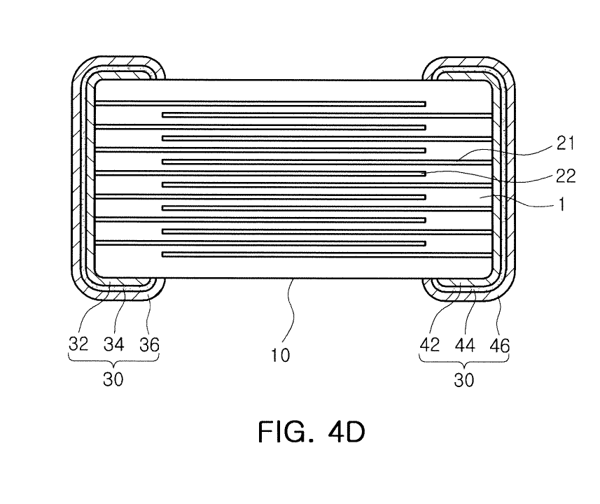

FIG. 3 is a flow chart schematically showing a method of manufacturing an electronic component according to the embodiment of the present invention, and FIGS. 4A through 4D are cross-sectional views describing the method of manufacturing an electronic component of FIG. 3.

Referring to FIGS. 3 through 4D, the method of manufacturing an electronic component, that is, a multilayer ceramic capacitor according to the embodiment of the present invention, may include preparing the ceramic body 10 in the form of a chip (S410) as shown in FIG. 4A.

The ceramic body 10 may have a rectangular parallelepiped shape, but is not limited thereto. The preparing of the ceramic body 10 in the form of a chip is not particularly limited, but the ceramic body 10 may be prepared by a general method of manufacturing a ceramic multilayer body.

More specifically, first, a plurality of ceramic green sheets may be prepared. Here, the ceramic green sheet may be manufactured by mixing ceramic powder, a binder, and a solvent to prepare a slurry and forming the prepared slurry as a sheet having a thickness of several μm by a doctor blade method.

Next, internal electrode patterns are formed by applying a conductive paste forming internal electrodes 21 and 22 on surfaces of the ceramic green sheets. In this case, the internal electrode patterns may be formed by a screen printing method, but is not limited thereto.

The conductive paste may be manufactured by dispersing a powder formed of nickel (Ni) or a nickel (Ni) alloy into an organic binder and an organic solvent. Here, as the organic binder, an organic binder known in the art may be used, but is not limited thereto. For example, a binder formed of a cellulose based resin, an epoxy resin, an arylic resin, an acrylic resin, a phenol-formaldehyde resin, an unsaturated polyester resin, a polycarbonate resin, a polyamide resin, a polyimide resin, an alkyd resin, rosin ester, or the like, may be used.

In addition, as the organic solvent, an organic solvent known in the art may be used, but is not limited thereto. For example, a solvent such as butylcarbitol, butylcarbitol acetate, turpentine oil, α-terpineol, ethyl cellosolve, butylphthalate, or the like, may be used.

Next, a process of stacking and pressurizing the ceramic green sheets including internal electrode patterns formed thereon to compress the stacked ceramic green sheets and the internal electrode patterns is performed.

When a ceramic multilayer body in which the ceramic green sheets and the internal electrode patterns are alternately stacked is manufactured as described above, the ceramic body 10 in the form of a chip may be prepared through a process of firing and cutting the ceramic multilayer body. Therefore, the ceramic body 10 may be formed in a shape in which a plurality of dielectric layers 1 and internal electrodes 21 and 22 are alternately stacked.

Then, the method of manufacturing an electronic component according to the embodiment of the present invention may include forming the electrode layers 32 and 42 on the external surfaces of the ceramic body 10 (S420) as shown in FIG. 4B.

The electrode layers 32 and 42 may be formed of copper (Cu), silver (Ag), palladium (Pd), or platinum (Pt). The electric layers 32 and 42 may be formed by applying a conductive paste to the external surfaces of the ceramic body 10 and firing the applied conductive paste, and in this case the conductive paste may be prepared by adding a glass frit to a copper (Cu) powder, a silver (Ag) powder, a palladium (Pd) powder, or a platinum (Pt) powder. A method of applying the conductive paste is not particularly limited. For example, a dipping method, a painting method, a printing method, or the like, may be used.

Then, the method of manufacturing an electronic component according to the embodiment of the present invention include forming the nickel (Ni) layers 34 and 44 by applying a conductive paste containing a nickel powder to the external surfaces of the electrode layers 32 and 42 and firing the applied conductive paste (S430) as shown in FIG. 4C. Here, a method of applying the conductive paste is not particularly limited. For example, various methods such as a dipping method, a painting method, a printing method, or the like, may be used.

Preferably, the nickel (Ni) layers 34 and 44 may be formed on the external surfaces of the electrode layers 32 and 42 to have a thickness of 0.1 to 10 μm by performing firing thereon at 600 to 900° C.

Next, the method of manufacturing an electronic component according to the embodiment of the present invention include forming the tin (Sn) layers 36 and 46 by applying a conductive paste containing a tin powder to the external surfaces of the nickel (Ni) layers 34 and 44 and firing the applied conductive paste (S440) as shown in FIG. 4D. Here, a method of applying the conductive paste is not particularly limited. For example, various methods such as a dipping method, a painting method, a printing method, or the like, may be used.

Preferably, the tin (Sn) layers 36 and 46 may be formed on the external surfaces of the nickel (Ni) layers 34 and 44 to have a thickness of 0.1 to 10 μm by performing firing thereon at 200 to 400° C.

In addition, the thickness of the nickel (Ni) layers 34 and 44 and the tin (Sn) layers 36 and 46 may increase when the nickel (Ni) layers 34 and 44 and the tin (Sn) layers 36 and 46 are formed by the dipping method, but it may be within a range of 1 to 10 μm.

Meanwhile, in the case in which an electro-deposition method is used as the method of forming the nickel (Ni) layers 34 and 44 and the tin (Sn) layers 36 and 46 on the external surfaces of the electrode layers 32 and 42, a plating solution may infiltrate into a portion of the electrode layers in which the electrode layers are not compact due to a reduction in thickness thereof.

The plating solution may infiltrate into the electrode layers 32 and 42, such that reliability of the multilayer ceramic electronic component may be significantly reduced due to degradation caused by a reaction between the plating solution and the internal electrode.

Further, in the case in which the electro-deposition method is performed in a state in which the plating solution is present in the electrode layers 32 and 42 or encloses a weak portion of the ceramic body, crack defects may be generated in the ceramic body due to hydrogen pressure generated during electro-deposition.

According to the embodiment of the present invention, the nickel (Ni) layers 34 and 44 and the tin (Sn) layers 36 and 46 are formed on the external surfaces of the electrode layers 32 and 42 by dipping the external surfaces of the electrode layers into a conductive paste containing a metal and performing firing thereon, rather than using the electro-deposition method, such that the above defects may be solved.

In the method of manufacturing an electronic component according to the embodiment of the present invention configured as described above, in a process of forming the external electrodes 30 and 40, the method of using the plating solution according the related art is not used, but the method of forming the nickel (Ni) layers 34 and 44 and the tin (Sn) layers 36 and 46 by the firing method after dipping the external surfaces of the electrode layers into the conductive paste may be used.

In the case in which the plating solution infiltrates into the external electrodes, reliability of the electronic component may be significantly reduced due to degradation caused by a reaction between the plating solution and the internal electrode. However, in the method of manufacturing an electronic component according to the embodiment of the present invention, since a plating process using the plating solution is not included, a defect such as damage to the electronic component due to the infiltration of the plating solution thereinto, or the like, may be solved. Therefore, reliability of the electronic component may be significantly improved.

In a method of manufacturing the ceramic electronic component according to another embodiment of the present invention, a description overlapped with the description of the ceramic electronic component according to the embodiment of the present invention described above will be omitted.

As set forth above, according to the embodiments of the present invention, the nickel (Ni) layers and the tin (Sn) layers are formed on the surfaces of the external electrodes formed of copper (Cu) by the firing method, such that compactness of the external electrode and reliability in the multilayer electronic component can be simultaneously improved.

While the present invention has been shown and described in connection with the embodiments, it will be apparent to those skilled in the art that modifications and variations can be made without departing from the spirit and scope of the invention as defined by the appended claims.

What is claimed is:

1. A method of manufacturing a multilayer ceramic electronic component, the method comprising:
preparing a ceramic body including internal electrodes;
forming electrode layers including at least one conductive metal selected from a group consisting of copper (Cu), silver (Ag), palladium (Pd), and platinum (Pt), an alloy thereof, or a coating material and electrically connected to the internal electrodes on external surfaces of the ceramic body;
forming nickel (Ni) layers on external surfaces of the electrode layers by a firing method; and
forming tin (Sn) layers on external surfaces of the nickel (Ni) layers by a firing method.

2. The method of manufacturing a multilayer ceramic electronic component of claim 1, wherein the nickel (Ni) layers and the tin (Sn) layers have a thickness of 1 to 10 μm.

3. The method of manufacturing a multilayer ceramic electronic component of claim 1, wherein the nickel (Ni) layers have a thickness of 0.1 to 10 μm.

4. The method of manufacturing a multilayer ceramic electronic component of claim 1, wherein the tin (Sn) layers have a thickness of 0.1 to 10 μm.

5. The method of manufacturing a multilayer ceramic electronic component of claim 1, wherein the nickel (Ni) layers are fired at a temperature of 600 to 900° C.

6. The method of manufacturing a multilayer ceramic electronic component of claim 1, wherein the tin (Sn) layers are fired at a temperature of 200 to 400° C.

7. A multilayer ceramic electronic component comprising:
a ceramic body including dielectric layers;
internal electrodes disposed to face each other and having the dielectric layers interposed therebetween; and
external electrodes electrically connected to the internal electrodes,
wherein the external electrodes include:
electrodes layers formed of at least one conductive metal selected from a group consisting of copper (Cu), silver (Ag), palladium (Pd), and platinum (Pt), an alloy thereof, or a coating material and electrically connected to the internal electrodes;
nickel (Ni) layers formed on external surfaces of the electrode layers; and
tin (Sn) layers formed on external surfaces of the nickel (Ni) layers,
wherein the nickel (Ni) layers and the tin (Sn) layers have a thickness of 1 to 10 μm.

8. The multilayer ceramic electronic component of claim 7, wherein the nickel (Ni) layers have a thickness of 0.1 to 10 μm.

9. The multilayer ceramic electronic component of claim 7, wherein the tin (Sn) layers have a thickness of 0.1 to 10 μm.

10. The multilayer ceramic electronic component of claim 7, wherein the nickel (Ni) layers are fired at a temperature of 600 to 900° C.

11. The multilayer ceramic electronic component of claim 7, wherein the tin (Sn) layers are fired at a temperature of 200 to 400° C.
